(19) United States
(12) Patent Application Publication
(10) Pub. No.: US 2025/0159817 A1
(43) Pub. Date: May 15, 2025

(54) DISPLAY DEVICE AND METHOD OF MANUFACTURING THE SAME

(71) Applicant: Samsung Display Co., Ltd., Yongin-Si (KR)

(72) Inventors: Myung Hwan KIM, Yongin-si (KR); Se Joong SHIN, Yongin-si (KR); Se Hyung CHO, Yongin-si (KR)

(21) Appl. No.: 18/754,151

(22) Filed: Jun. 26, 2024

(30) Foreign Application Priority Data
Nov. 13, 2023 (KR) 10-2023-0156826

(51) Int. Cl. H05K 5/02; H05K 7/20

(52) U.S. Cl. CPC H05K 5/02; H05K 7/20963

(57) ABSTRACT

A display device comprises a display panel comprising a first area comprising a display area, a second area spaced apart from the first area, and a bendable third area between the first area and the second area; a bonding layer in the second area and the third areal and located on a first surface of the display panel; an panel bottom cover in the first area of the display panel and located on the first surface; a first support film in the second area and bonded to the bonding layer; a second support film in the third area and bonded to the bonding layer; and a gap in the third area and separating the first support film from the second support film.

This application claims the benefit of Korean Patent Application No. 10-2023-0156826, filed on Nov. 13, 2023, in the Korean Intellectual Property Office, the disclosure of which is incorporated herein in its entirety by reference.

### BACKGROUND

### Field

The present disclosure relates to a display device and a method of manufacturing the same.

### Description of the Related Art

Display devices are used today for displaying images in many applications. For example, various electronic devices such as smartphones, digital cameras, notebook computers, navigation devices, and smart televisions employ display devices. Some popular types of display devices are liquid crystal displays (LCD) and organic light emitting displays (OLED). OLEDs display images using organic light emitting elements that generate light through recombination of electrons and holes. An OLED typically includes a plurality of transistors in a pixel circuit that provides a driving current to an organic light emitting element. Attempts have been made to minimize the thickness of display devices in order to make them lighter.

### SUMMARY

Aspects of the present disclosure may provide a display device with a reduced risk of crack formation in wirings of a display panel when the display panel is bent, may reduce thickness and manufacturing costs of a display device, and may provide a method of manufacturing display devices with reduced crack formation, reduced thickness, or reduced costs.

Aspects of the present disclosure are not restricted to the ones set forth herein. The above and other aspects of the present disclosure will become more apparent to one of ordinary skill in the art to which the present disclosure pertains by referring to the detailed description of the present disclosure given below.

According to an aspect of the present disclosure, a display device may include: a display panel comprising a first area comprising a display area, a second area spaced apart from the first area, and a bendable third area located between the first area and the second area; a bonding layer disposed in the second area and the third area of the display panel and located on a first surface of the display panel; an panel bottom cover disposed in the first area of the display panel and located on the first surface of the display panel; a first support film disposed in the second area of the display panel and bonded to the bonding layer; a second support film disposed in the third area of the display panel and bonded to the bonding layer; and a gap provided in the third area to separate the first support film and the second support film from each other.

In an embodiment, the bonding layer may comprise a light-peelable adhesive of a type having an adhesive strength of 100 gf/inch or less after light irradiation.

In an embodiment, the first support film may further comprise a burr pattern protruding downward from a first surface of the first support film along an inner surface adjacent to the gap.

In an embodiment, an angle formed by the inner surface on which the burr pattern is formed and a first surface of the bonding layer which contacts the first support film may be 70 degrees or less.

In an embodiment, the display device may further include a driving chip disposed in the second area of the display panel and located on a second surface of the display panel opposite the first surface of the display panel.

In an embodiment, the display device may further include a flexible printed circuit board electrically connected to the driving chip of the second area; and a substrate cover layer formed on a first surface of the flexible printed circuit board, wherein an end of the flexible printed circuit board may be bonded to an edge of the display panel in the second area, and the substrate cover layer may be located on the first surface of the flexible printed circuit board at the edge of the display panel and contacts the display panel, the bonding layer and the first support film in the second area.

In an embodiment, the substrate cover layer may further include a cover portion extending from a first surface located on a lower side of the substrate cover layer toward the first support film which contacts the substrate cover layer and covering a portion of a lower area of the first support film.

In an embodiment, the display device may further include a protective layer formed on the second surface of the display panel opposite the first surface of the display panel in the third area.

In an embodiment, the display device may further include a support film connection portion formed on the first surface of the bonding layer exposed to the gap and connecting the first support film and the second support film.

In an embodiment, the first surface of the display panel may be exposed to the gap in the third area, and the bonding layer may comprise a first bonding layer disposed in the second area and a second bonding layer spaced apart from the first bonding layer with the gap interposed therebetween in the third area.

In an embodiment, the bonding layer and the second support film extend to a part of the first area to additionally lie in the first area, a side surface of the bonding layer and a side surface of the second support film face a side surface of the panel bottom cover, and the display device further comprises a support film connection portion formed on the first surface of the bonding layer exposed to the gap and connecting the first support film and the second support film.

According to another aspect of the present disclosure, there is provided a display device comprising: a display panel comprising a first area comprising a display area, a second area spaced apart from the first area, and a bendable third area located between the first area and the second area; a bonding layer disposed in the second area and the third area of the display panel and located on a first surface of the display panel; a first support film disposed in the second area of the display panel and bonded to the bonding layer; a second support film disposed in the third area of the display panel at a position spaced apart from the first support film and bonded to the bonding layer; a flexible printed circuit board having an end bonded to a distal area of the display panel in the second area; and a substrate cover layer formed on a first surface of the flexible printed circuit board.

In an embodiment, the substrate cover layer may further comprise a cover portion extending from a first surface located on a lower side of the substrate cover layer toward the first support film which contacts the substrate cover layer and covering a portion of a lower area of the first support film.

In an embodiment, the bonding layer may comprise a light-peelable adhesive of a type having an adhesive strength of 100 gf/inch or less after light irradiation.

In an embodiment, the display device may further include a panel bottom cover disposed in the first area of the display panel, contacting the bonding layer and the second support film, and located on the first surface of the display panel.

In an embodiment, the panel bottom cover may comprise an adhesive member bonded to the first surface of the display panel in the first area, a heat dissipation member bonded to the adhesive member and dissipating heat of the display panel and a bending adhesive member bonded to the heat dissipation member and fixing a bending position of the display panel when the display panel is bent, the third area comprises a gap which is a space formed between the first support film and the second support film, and the first support film may further comprise a burr pattern protruding downward from a first surface of the first support film along an inner surface adjacent to the gap.

In an embodiment, the display device may further include a driving chip disposed in the second area of the display panel and located on a second surface of the display panel opposite the first surface of the display panel.

In an embodiment, the display device may further include a protective layer formed on the second surface of the display panel opposite the first surface of the display panel in the third area.

According to another aspect of the present disclosure, there is provided a display device comprising: a display panel comprising a first area comprising a display area, a second area spaced apart from the first area, and a bendable third area located between the first area and the second area; an panel bottom cover disposed in the first area of the display panel and located on a first surface of the display panel; a bonding layer disposed in the second area, the third area and a part of the first area of the display panel, contacting the panel bottom cover of the first area, and located on the first surface of the display panel; a first support film disposed in the second area of the display panel and bonded to the bonding layer; a second support film disposed in the first area of the display panel, contacting the panel bottom cover of the first area, and bonded to the bonding layer; and a gap provided in the third area of the display panel as a space between the first support film and the second support film, wherein the bonding layer has a first surface exposed to the gap in the third area and comprises a first adhesive layer located on the first surface of the display panel and a second adhesive layer contacting the first adhesive layer.

According to another aspect of the present disclosure, there is provided a method of manufacturing a display device having a display panel which comprises a first area comprising a display area, a second area spaced apart from the first area, and a bendable third area comprising a gap between the first area and the second area, the method comprising: preparing a mother substrate structure which comprises a light-peelable bonding body layer and a support film layer; forming cutting lines in the mother substrate structure and forming a first support film in the second area and a second support film in the third area and forming the gap between the first and second support films; separating a display cell from the mother substrate structure to prepare the display panel; selectively irradiating light to the first area of the display panel; peeling and removing the support film layer of the first area irradiated with the light; and forming an panel bottom cover in the first area from which the support film layer has been peeled off, such that the panel bottom cover contacts the second support film of the third area.

In an embodiment, in the step of forming the cutting line, the cutting line may be formed by cutting the support film layer through laser processing or cutting the support film layer and the light-peelable bonding body layer.

In an embodiment, in the step of forming the cutting line, a burr pattern protruding from the support film may be formed in the incision area where the cutting line is formed.

In an embodiment, in the step of forming the cutting line, a cutting surface is formed in the support film layer, and an inclination angle formed between the cut surface and the lower surface of the bonding layer may be 70 degrees or less.

In an embodiment, in the step of irradiating the light, a mask including a light transmitting portion corresponding to the first region and a light blocking portion corresponding to the second and third regions may be disposed based on the incision line.

In an embodiment, in the step of forming the panel bottom cover may include forming an adhesive member on the display panel in the first area, forming a heat dissipation member coupled to the adhesive member to radiate heat of the display panel, and It may include forming a bending adhesive member that is coupled to the heat dissipation member and fixes the bending position of the display panel when it is bent.

In an embodiment, the method may further include in the third region, the method may further include forming a protective layer on at least one of the upper surface of the display panel and the lower surface of the bonding layer.

In an embodiment, the method may further include forming a driving chip disposed in the second area of the display panel and located on an upper surface of the display panel.

In an embodiment, the method may further include forming a flexible printed circuit board electrically connected to the driving chip and having one end coupled to a distal end region of the display panel in the second region, and positioned on a lower surface of the flexible printed circuit board in the distal region of the display panel; The method may further include forming a substrate cover layer in contact with a side surface of the display panel, a side surface of the bonding layer, and a side surface of the support film in the second region.

In an embodiment, in the step of forming the substrate cover layer, the cover portion extending from the lower surface of the substrate cover layer toward the side of the support film in contact with one side of the substrate cover layer and covering a portion of the lower region of the support film may be formed.

According to the present disclosure, a second support film is located in an area where bending begins when a display panel is bent. That is, the second support film is located in a start area of a third area, which is a bending area, to contact a panel bottom cover. Therefore, when the display panel is bent, the under-cover panel and the display panel can be prevented from directly contacting and interfering with each other, thus reducing the risk of crack formation in wirings of the display panel. If the second support film is not provided unlike in the present disclosure, bending stress may occur in the area where bending begins, thus increasing the risk of crack formation.

In addition, the second support film may support the panel bottom cover while in contact with the panel bottom cover. Therefore, when a variable motion, that is, bending of the display panel occurs, the second support film may support the panel bottom cover from the side and stably maintain the position of the panel bottom cover.

In addition, the second support film supports the display panel from below and contacts the panel bottom cover from the side. Therefore, when the display panel is bent, the second support film can support the display panel and the panel bottom cover so that symmetrical positions of structures stacked on the display panel are not affected by the bending operation, that is, so that the structures can be bent symmetrically.

In addition, since a bonding layer is formed in a second area and the third area, a first support film and the second support film in different areas can all be bonded to the display panel using one bonding layer. Therefore, the number of components for bonding the above films can be reduced, thereby reducing thickness and manufacturing costs. In addition, since the process of bonding each of the above films is simplified, the efficiency of a manufacturing process can be improved.

If the first support film is disposed in a first area, the position of a neutral plane may be changed by the first support film when the display panel is bent or folded.

However, in the present disclosure, the first support film is not disposed in the first area but is located in the second area, and the second support film is located in the third area. In this case, the position of the neutral plane can be kept unchanged.

In addition, if the first support film is located in the first area, the overall thickness may increase because stacked structures increase in the first area which is a display area. However, in the present disclosure, the first and second support films are located in the second and third areas which are non-display areas, and the first support film is not disposed in the first area which includes the display area. In this case, the stacked structures can be reduced in the first area which is the display area, thereby reducing the overall thickness of a display device.

In addition, a cover portion may be formed adjacent to the first support film of the second area to seal a portion of a lower surface of the first support film. Therefore, it is possible to prevent the penetration of moisture into a flexible printed circuit board and a driving chip connected to the flexible printed circuit board, thereby preventing corrosion due to the moisture.

In the manufacturing process, a support film layer may be bonded and then peeled off by a light-peelable adhesive layer whose adhesive strength is reduced by light irradiation. Therefore, the support film layer does not remain to cause defects and does not leave damage on a peeled surface. Accordingly, a defect rate can be reduced, and issues such as tearing during a peeling process can be suppressed.

However, aspects of the present disclosure are not restricted to the one set forth herein. The above and other aspects of the present disclosure will become more apparent to one of ordinary skill in the art to which the present disclosure pertains by referencing the claims.

### BRIEF DESCRIPTION OF THE DRAWINGS

These and/or other aspects will become apparent and more readily appreciated from the following description of the embodiments, taken in conjunction with the accompanying drawings.

FIG. 1 is a perspective view of a display device according to an embodiment.

FIG. 2 is a plan view of the display device illustrated in FIG. 1.

FIG. 3 is a rear view of the display device illustrated in FIG. 1.

FIG. 4 is a rear view of a display panel in the display device of FIG. 3.

FIG. 5 is a cross-sectional view schematically illustrating the structure of the display panel of FIG. 4.

FIG. 6 is an enlarged cross-sectional view of the stacked structure of the display panel of FIG. 5.

FIG. 7 is a cross-sectional view taken along line X1-X1′ of FIGS. 2 and 3.

FIG. 8 is an enlarged view of a first area of FIG. 7.

FIG. 9 is an enlarged view of a second area of FIG. 7.

FIG. 10 is an enlarged view of the second area, a third area, and a part of the first area in FIG. 7 according to a first embodiment.

FIG. 11 is an enlarged view of the second area, the third area, and a part of the first area in FIG. 7 according to a second embodiment.

FIG. 12 is an enlarged view of the second area, the third area, and a part of the first area in FIG. 7 according to a third embodiment.

FIG. 13 is an enlarged view of the second area, the third area, and a part of the first area in FIG. 7 according to a fourth embodiment.

FIG. 14 is an enlarged view of the second area, the third area, and a part of the first area in FIG. 7 according to a fifth embodiment.

FIG. 15 is an enlarged view of the second area and a flexible printed circuit board bonding area of FIG. 7.

FIG. 16 is a cross-sectional view of the display device of FIG. 7 in a bent state.

FIG. 17 is a flowchart illustrating a method of manufacturing a display device according to an embodiment of the present disclosure.

FIG. 18 is a perspective view of an embodiment of a mother substrate for a display device.

FIG. 19 is a rear view of the mother substrate for a display device illustrated in FIG. 18.

FIGS. 20, 21, 22, 23, 24, and 25 are cross-sectional views of structures created during a process of forming first and second support films, a bonding layer, and a panel bottom cover during the manufacturing process of FIG. 17.

### DETAILED DESCRIPTION

Example embodiments of the present disclosure will now be described more fully hereinafter with reference to the accompanying drawings. Devices and processes described herein may, however, be embodied in different forms and should not be construed as limited to the example embodiments set forth herein. Rather, these embodiments are provided so that this disclosure will be thorough and complete and will convey to those skilled in the art an understanding of the subject matter defined by the claims.

In the following, a layer referred to as being “on” another layer or substrate may be directly on the other layer or substrate, or intervening layers may also be present. Likewise, “below”, “left”, and “right” include cases where one or more elements may be directly adjacent to other elements or cases where another element, layer or material is interposed.

The terms “first,” “second,” etc. may be used herein to describe various elements, but these elements should not be limited by these terms. These terms are only used to distinguish one element from another element. For instance, a first element discussed below could be termed a second element without departing from the teachings of the present disclosure. Similarly, the second element could also be termed the first element.

Features of each of various embodiments of the present disclosure may be partially or entirely combined with each other and may variously interwork with each other, and respective embodiments may be implemented independently of each other or may be implemented together in association with each other.

Hereinafter, embodiments of the present disclosure will be described with reference to the accompanying drawings. The same reference numbers used in the drawings and throughout the specification indicate the same or similar components. In the drawings, the thickness of layers and regions may be exaggerated or otherwise altered for clarity or ease of illustration.

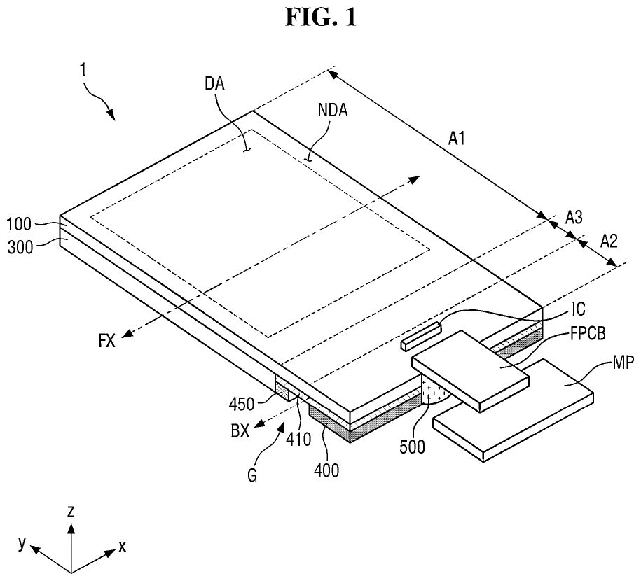

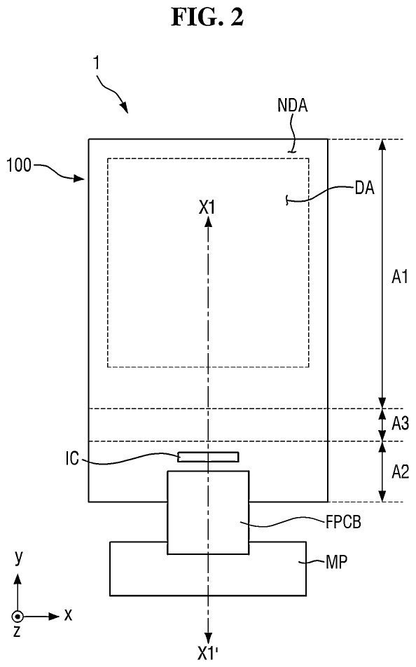

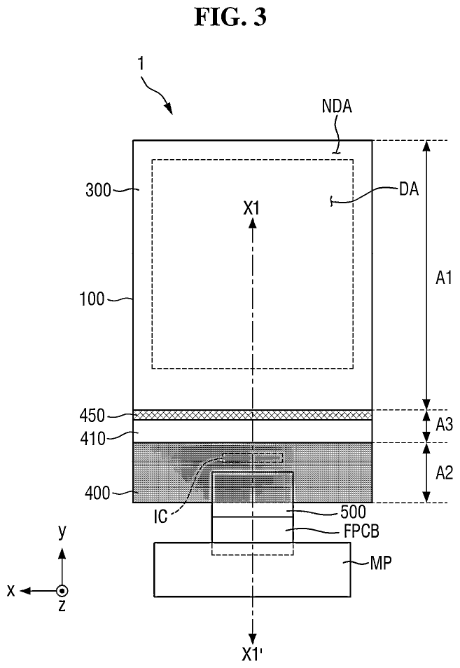

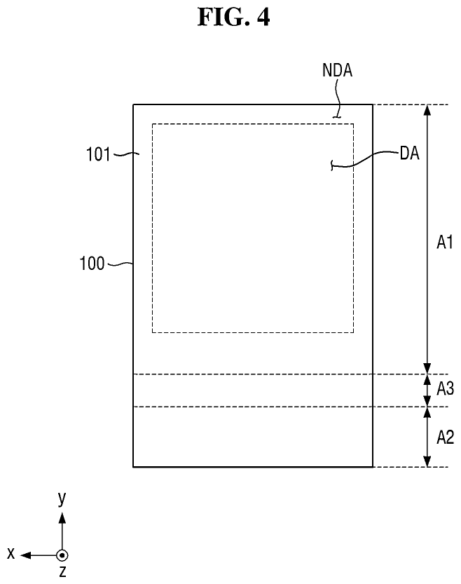

FIG. 1 is a perspective view of a display device 1 according to an embodiment. FIG. 2 is a plan view of the display device 1 illustrated in FIG. 1. FIG. 3 is a rear view of the display device 1 illustrated in FIG. 1. FIG. 4 is a rear view of a display panel 100 in the display device 1 of FIG. 3. Here, FIGS. 1 through 4 illustrate the display device 1 in a flat state before the display device 1 is bent or folded.

The display device 1 may be applied to a portable terminal or the like. Examples of the portable terminal may include tablet PCs, smartphones, personal digital assistants (PDAs), portable multimedia players (PMPs), game consoles, and wristwatch-type electronic devices. However, the present disclosure is not limited to the specific type of display device 1. For example, in other embodiments of the present disclosure, the display device 1 may be used in small or medium-sized electronic equipment such as PCs, notebook computers, car navigation devices and cameras as well as in large-sized electronic equipment such as televisions and outdoor billboards.

In an embodiment, the display panel 100 in the display device 1 may have a rectangular shape. The display panel 100 may have a rectangular shape in plan view and may include both short sides, both long sides, and a rectangular panel surface bounded by the short sides and the long sides. FIG. 1 illustrates the display panel 100 as having a rectangular planar shape in which each corner where a long side and a short side meet is right-angled. However, the present disclosure is not limited thereto. The corners of the display panel 100 may alternatively be curved, and the planar shape of the display panel 100 may also be circular or other various shapes.

Based on FIG. 1, the short sides of the display panel 100 may be described as extending in a first direction x, the long sides of the display panel 100 may be described as extending in a second direction y, and a direction perpendicular to the panel surface of the display panel 100 may be described as a third direction z. In addition, unless otherwise defined below, in the present specification, “above”, “top”, “upper surface”, and “upper side” refer to a direction in which an arrow of the third direction z points with respect to the display panel 100 shown in FIG. 1, and “below”, “bottom”, “lower surface”, and “lower side” refer to a direction opposite to the direction in which the arrow of the third direction z points with respect to the display panel 100 shown in FIG. 1.

The display panel 100 may be a display panel 100 including a self-light emitting element. In an exemplary embodiment, the self-light emitting element may include at least one of an organic light emitting diode, a quantum dot light emitting diode, an inorganic material-based micro light emitting diode (e.g., micro LED), and an inorganic material-based nano light emitting diode (e.g., nano LED). For ease of description, each element of the display panel 100 will be described in detail below using an example in which the self-light emitting element is an organic light emitting element.

The area of the display panel 100 may be divided or partitioned based on image display. The display panel 100 may thus include a display area DA, which displays an image, and a non-display area NDA, which does not display an image. The non-display area NDA may be located around the display area DA and may surround the display area DA.

The area of the display panel 100 may also be divided or partitioned based on bending, and the display panel 100 may thus include a first area A1, a second area A2, and a third area A3.

The first area A1 may be spaced apart from the second area A2, may include the display area DA, and may be foldable. For example, the first area A1 may be folded upward or downward about a folding axis FX extending along the first direction x. That is, the first area A1 can be folded about the folding axis FX so that the folding reorients a portion of the first area A1 shown in FIG. 1 as having a normal in the direction in which the arrow of the third direction z points, that is, the upward direction, to an orientation in which the normal of the folded portion is in the direction opposite to the direction in which the arrow of the third direction z points, that is, the downward direction.

The second area A2 may be spaced apart from the first area A1 and may be a part of the non-display area NDA.

The third area A3 may be another part of the non-display area NDA and may be between the first area A1 and the second area A2. The third area A3 may include a gap G located between the first area A1 and the second area A2. The gap G may be formed to cross the non-display area NDA along the first direction x which is a short-side direction of the display panel 100.

The display panel 100 can be bent about on a bending axis BX extending along the first direction x in the third area A3 and can particularly be bent downward about the bending axis BX in the third area A3. A part of the non-display area NDA of the display panel 100 may thus be bent around toward the bottom of the display panel 100, so that a portion of the non-display area NDA of the display device 1 that is visible from above may be reduced, and a bezel width of the display device 1 may be reduced.

One or more driving chips IC may be disposed on the display panel 100 in the second area A2, and the second area A2 may contain pads connected to the driving chips IC. The driving chips IC may include at least one of driving devices such as a data driver that transmits data signals to data lines, a gate driver that transmits gate signals to gate lines, and a signal controller that controls the operations of the data driver and the gate driver. The display panel 100 is not limited to having a single driving chip as shown in the illustrated example.

The driving chip IC may be mounted on the display panel 100 using a chip on plastic method. The driving chip IC may be mounted on the display panel 100 using a pressurizing device. The driving chip IC may be mounted on the display panel 100 using an anisotropic conductive film. Alternatively, in an embodiment, the driving chip IC may be mounted on the display panel 100 using an ultrasonic bonding method without a separate anisotropic conductive film.

Ultrasonic bonding is a method of joining two metals by applying pressure and ultrasonic vibration. When the driving chip IC is mounted on the display panel 100 using the ultrasonic bonding method, a process of applying pressure and ultrasonic vibration to the driving chip IC may be performed. However, the present disclosure is not limited to the above-described embodiments. In an embodiment, the driving chip IC may be mounted on a flexible printed circuit board FPCB in the form of a chip on film.

An end of the flexible printed circuit board FPCB may be located on an edge of the display panel 100 in the second area A2. The flexible printed circuit board FPCB may be connected to the pads provided on the display panel 100, e.g., by an anisotropic conductive film or the like. The process of connecting the flexible printed circuit board FPCB to the display panel 100 may include a process of applying pressure to the flexible printed circuit board FPCB.

A main circuit board MP may be electrically connected to the display panel 100 through the flexible printed circuit board FPCB and may exchange signals with the driving chip IC. The main circuit board MP may provide image data, control signals, power supply voltages, etc. to the display panel 100 or the flexible printed circuit board FPCB. The main circuit board MP may include active and passive elements.

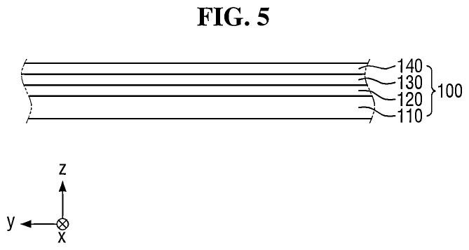

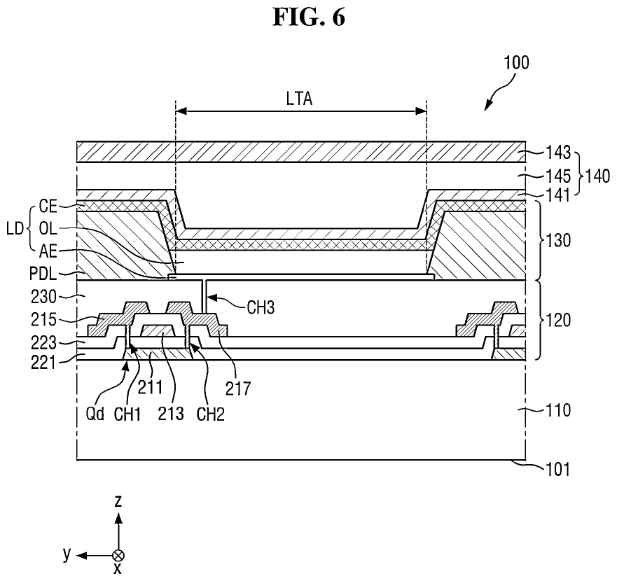

FIG. 5 is a cross-sectional view schematically illustrating the structure of the display panel 100. FIG. 6 is an enlarged cross-sectional view of the stacked structure of the display panel 100 of FIG. 5.

The display panel 100 may include a base substrate 110, a driving layer 120, an organic light emitting element layer 130, and an encapsulation layer 140.

The base substrate 110 provides a lower surface 101 of the display panel 100. The base substrate 110 may be a flexible substrate and may be made of a flexible polymer material. For example, the base substrate 110 may be made of plastic with excellent heat resistance and durability, such as polyethylene ether phthalate, polyethylene naphthalate, polycarbonate, polyarylate, polyetherimide, polyethersulfone, or polyimide. A case where the base substrate 110 includes polyimide will be described below as an example.

The driving layer 120 includes elements for providing signals to the organic light emitting element layer 130. The driving layer 120 may include various signal lines, for example, scan lines (not illustrated), data lines (not illustrated), power lines (not illustrated), and emission lines (not illustrated). The driving layer 120 may include a plurality of transistors and capacitors. The transistors may include a switching transistor (not illustrated) and a driving transistor Qd provided in each pixel (not illustrated).

FIG. 6 illustrates the driving transistor Qd of the driving layer 120 an example. The driving transistor Qd includes an active layer 211, a gate electrode 213, a source electrode 215, and a drain electrode 217 in the driving layer 120.

The active layer 211 may be disposed on the base substrate 110. The active layer 211 may include polycrystalline silicon. Alternatively, the active layer 211 may include monocrystalline silicon, low-temperature polycrystalline silicon, or amorphous silicon. However, the present disclosure is not limited thereto, and the active layer 211 may also include an oxide semiconductor.

The driving layer 120 may further include a first insulating layer 221 disposed on the active layer 211, and the gate electrode 213 may be located on the first insulating layer 221.

The first insulating layer 221 may insulate the active layer 211 and the gate electrode 213 from each other. The first insulating layer 221 may include an inorganic insulating material such as silicon oxide, silicon nitride, or silicon oxynitride. The first insulating layer 221 may be a single layer or a multilayer composed of stacked layers of different materials.

The gate electrode 213 may be located on the first insulating layer 221 and may overlap the active layer 211. The gate electrode 213 may include a conductive material or a metal such as gold (Au), silver (Ag), copper (Cu), nickel (Ni), platinum (Pt), palladium (Pd), aluminum (Al), or molybdenum (Mo).

The driving layer 120 may further include a second insulating layer 223 located on the gate electrode 213, and the source electrode 215 and the drain electrode 217 may be disposed on the second insulating layer 223.

The second insulating layer 223 may include at least any one of the insulating materials exemplified in the description of the first insulating layer 221.

The source electrode 215 and the drain electrode 217 may be connected to the active layer 211 through respective contact holes CH1 and CH2 provided in the first insulating layer 221 and the second insulating layer 223. The source electrode 215 and the drain electrode 217 may have, but are not limited to, a metal multilayer structure of titanium (Ti)/aluminum (Al)/titanium (Ti).

The driving layer 120 may further include a protective layer 230 disposed on the source electrode 215 and the drain electrode 217. In some embodiments, the protective layer 230 may be a planarization layer. For example, the protective layer 230 may include an organic insulating material or an inorganic insulating material or may be implemented as a composite of an organic insulating material and an inorganic insulating material.

Although the structure of the switching transistor is not illustrated in FIG. 6, the switching transistor (not illustrated) and the driving transistor Qd may have substantially the same structure or similar structures. However, the present disclosure is not limited thereto, and the switching transistor (not illustrated) and the driving transistor Qd may also have different structures. For example, an active layer (not illustrated) of the switching transistor (not illustrated) and the active layer 211 of the driving transistor Qd may be made of different materials or may be disposed on different layers.

The driving layer 120 may be located not only in the display area DA but also in the non-display area NDA of the display panel 100. A portion of the driving layer 120 which is located in the non-display area NDA, for example, a portion located in the non-display area NDA of the first area A1, the second area A2, or the third area A3 may include wirings and a pad unit electrically connected to the driving chip IC and may further include wirings and a pad unit electrically connected to the flexible printed circuit board FPCB.

The organic light emitting element layer 130 may include an organic light emitting element LD as a self-light emitting element. The organic light emitting element LD may be provided as a top emission type and may emit light in a thickness direction of the display panel 100, which is the third direction z.

The organic light emitting element LD may include a first electrode AE, an organic layer OL, and a second electrode CE.

The first electrode AE is disposed on the protective layer 230. The first electrode AE is connected to the drain electrode 217 through a contact hole CH3 formed in the protective layer 230. The first electrode AE may be a pixel electrode or an anode of the organic light emitting element LD. The first electrode AE may be a transflective electrode or a reflective electrode. When the organic light emitting element LD is provided as a top emission type, the first electrode AE may be a reflective electrode. The first electrode AE may include a reflective conductor such as any one or more of silver (Ag), magnesium (Mg), aluminum (Al), platinum (Pt), palladium (Pd), gold (Au), nickel (Ni), neodymium (Nd), iridium (Ir) and chromium (Cr), or an alloy thereof.

The first electrode AE may be a single layer made of metal oxide or metal or a multilayer structure having multiple layers. For example, the first electrode AE may have, but is not limited to, a single layer structure of indium tin oxide (ITO), silver (Ag) or a metal mixture (e.g., a mixture of Ag and Mg), a two-layer structure of indium tin oxide (ITO)/magnesium (Mg) or indium tin oxide (ITO)/magnesium fluoride (MgF), or a three-layer structure of indium tin oxide (ITO)/silver (Ag)/indium tin oxide (ITO).

The organic layer OL may include an organic emission layer (EML) made of a low-molecular organic material or a high-molecular organic material. The organic emission layer may emit light. The organic layer OL may optionally include a hole transport layer (HTL), a hole injection layer (HIL), an electron transport layer (ETL), and an electron injection layer (EIL), in addition to the organic emission layer.

Holes and electrons from the first electrode AE and the second electrode CE, respectively, are injected into the organic emission layer inside the organic layer OL. The holes and the electrons combine in the organic emission layer to form excitons, and light is emitted as the excitons fall from an excited state to a ground state.

The second electrode CE may be provided on the organic layer OL. The second electrode CE may be a common electrode that includes a cathode of the organic light emitting element LD. The second electrode CE may be a transmissive electrode or a transflective electrode. When the second electrode CE is a transflective electrode, it may include lithium (Li), lithium fluoride (LiF), calcium (Ca), lithium fluoride (LiF)/calcium (Ca), lithium fluoride (LiF)/aluminum (Al), aluminum (Al), magnesium (Mg), barium fluoride (BaF), barium (Ba), silver (Ag), or a compound or mixture thereof (e.g., a mixture of Ag and Mg). When the second electrode CE is a transmissive electrode, it may include a transparent metal oxide such as indium tin oxide (ITO), indium zinc oxide (IZO), zinc oxide (ZnO) or indium tin zinc oxide (ITZO) or may include molybdenum (Mo), titanium (Ti) or silver (Ag).

The organic light emitting element layer 130 may further include a pixel defining layer PDL disposed on the protective layer 230. The pixel defining layer PDL may include an opening overlying the first electrode AE in plan view and may define an emission area LTA.

The encapsulation layer 140 may be disposed on the organic light emitting element layer 130. The encapsulation layer 140 may protect the organic light emitting element layer 130 from external moisture and oxygen. The encapsulation layer 140 may be formed as thin-film encapsulation and may include one or more organic layers and one or more inorganic layers. For example, the encapsulation layer 140 may include a first inorganic layer 141 located on the second electrode CE, an organic layer 145 located on the first inorganic layer 141, and a second inorganic layer 143 located on the organic layer 145.

The first inorganic layer 141 may be disposed on the organic light emitting element LD and may prevent the penetration of moisture, oxygen, etc. into the organic light emitting element LD. In some embodiments, the first inorganic layer 141 may include an inorganic material, and the inorganic material may include, for example, any one or more of silicon oxide (SiOₓ), silicon nitride (SiNₓ), and silicon oxynitride (SiONₓ).

The organic layer 145 may be on the first inorganic layer 141. The organic layer 145 may improve flatness. The organic layer 145 may include an organic material, and the organic material may include, for example, any one of epoxy, acrylate, and urethane acrylate.

The second inorganic layer 143 may be located on the organic layer 145. The second inorganic layer 143 may perform substantially the same or similar role as the first inorganic layer 141 and may be made of substantially the same or similar material as the first inorganic layer 141. The second inorganic layer 143 may completely cover the organic layer 145. In some embodiments, the second inorganic layer 143 and the first inorganic layer 141 may contact each other outside the display area DA to form an inorganic-inorganic bond. The inorganic-inorganic bond may effectively prevent the introduction of moisture into the display device 1 from the outside of the display device 1.

Although each of the first inorganic layer 141, the organic layer 145, and the second inorganic layer 143 is illustrated as a single layer in FIG. 6, the present disclosure is not limited thereto. That is, at least one of the first inorganic layer 141, the organic layer 145, and the second inorganic layer 143 may alternatively be a multilayer structure.

The encapsulation layer 140 may not completely cover the non-display area NDA of the display panel 100. For example, the encapsulation layer 140 may be absent from a part of the first area A1 of the display panel 100 between the third area A3 and the display area DA and may be absent from the second area A2 and the third area A3. Alternatively, the encapsulation layer 140 may be in a part of the first area A1 of the display panel 100 between the third area A3 and the display area DA and may be absent from the second area A2 and the third area A3. For ease of description, a case where the encapsulation layer 140 is in the display area DA of the display panel 100, is absent from a part of the first area A1 between the third area A3 and the display area DA, and is absent from the second area A2 and the third area A3 will be described as an example.

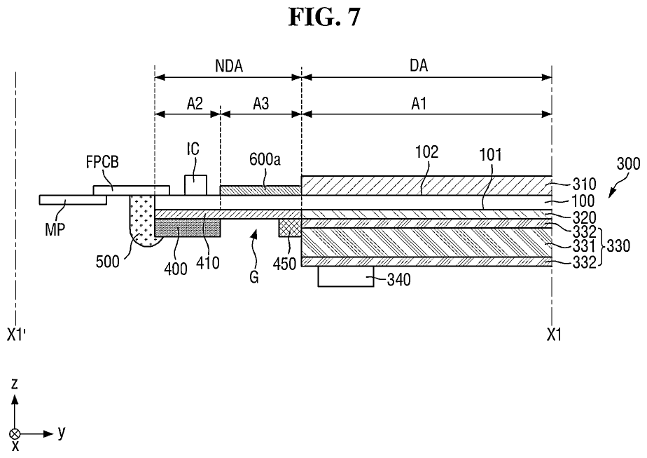

FIG. 7 is a cross-sectional view taken along line X1-X1′ of FIGS. 2 and 3 and a cross-sectional view of the display panel 100 on which a panel bottom cover 300, first and second support films 400 and 450, and a substrate cover layer 500 may be in the first through third areas A1 through A3.

The panel bottom cover 300 may be bonded to the lower surface 101, i.e., a first surface of the display panel 100, in the first area A1 spaced apart from the first support film 400 and may support the display panel 100.

A polarizer 310 is located on the panel bottom cover 300 with the display panel 100 interposed between the polarizer 310 and the panel bottom cover 300. The polarizer 310 may be located on an upper surface 102, i.e., a second surface of the display panel 100, may increase contrast ratio in a displayed image by expressing true black, and may improve outdoor visibility of the displayed image.

The panel bottom cover 300 may include an adhesive member 320 attached to the lower surface 101 of the display panel 100, a heat dissipation member 330 for efficiently dissipating heat from the display panel 100, and a bending adhesive member 340 for fixing a bent state of the display panel 100 when the display panel 100 is bent.

The adhesive member 320 is interposed between the display panel 100 and the heat dissipation member 330 to attach the panel bottom cover 300 to the display panel 100. The adhesive member 320 may be an adhesive layer made of a pressure sensitive adhesive (PSA) and may attach the panel bottom cover 300 to the display panel 100. For example, the adhesive member 320 may include, but is not limited to, an acrylic or silicone adhesive. The adhesive member 320 may be formed as a pressure sensitive adhesive layer that further includes a light absorbing material such as black pigment or black dye to absorb light incident from outside the display panel 100.

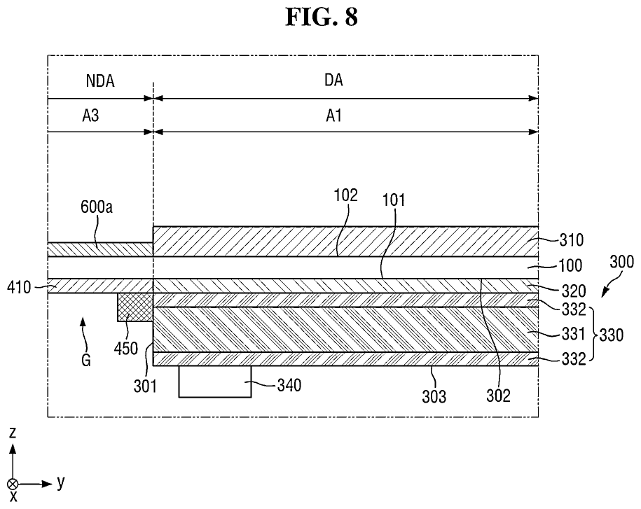

The heat dissipation member 330 may be bonded by the adhesive member 320 and may include a metal layer 331 and a plating layer 332, which may be formed on at least one of upper and lower surfaces of the metal layer 331. The metal layer 331 may be, but is not limited to, a thin film made of one or more metals or materials selected from copper, nickel, ferrite, and silver with excellent thermal conductivity. The plating layer 332 may be made of the same or different metal or material as used in the metal layer 331. Although FIG. 8 shows the plating layer 332 on both the upper and lower surfaces of the metal layer 331, the plaiting layer 332 may alternatively be formed on only one surface of the metal layer 331.

The heat dissipation member 330 may also be, but is not limited to, a composite layer including, for example, a first layer containing graphite or carbon nanotubes and a second layer made of a thin film of a material such as copper, nickel, ferrite, or silver, which can shield electromagnetic waves and has excellent thermal conductivity.

The bending adhesive member 340 fixes the bent state of the display panel 100 when the display panel 100 is bent. The bent state of the display panel 100 may be fixed by bending the display panel 100 to bring the first support film 400 into contact with the bending adhesive member and attaching the first support film 400 to the bending adhesive member 340. The bending adhesive member 340 may include, but is not limited to, an acrylic or silicone adhesive.

The panel bottom cover 300 may further include a buffer member (not illustrated). The buffer member may be located on the heat dissipation member 330 and the bending adhesive member 340. The buffer member (not illustrated) may be formed as a cushion layer to support the display panel 100 and prevent damage to the display panel 100 by absorbing external shock. For example, the buffer member (not illustrated) may be made of polymer resin such as polyurethane, polycarbonate, polypropylene or polyethylene or may be made of an elastic material such as a sponge formed by foam molding rubber, a urethane-based material, or an acrylic-based material.

The first support film 400 is spaced apart from the heat dissipation member 330 of the panel bottom cover 300 with the second support film 450 interposed between the first support film 400 and the heat dissipation member 330. The first support film 400 is spaced apart in a horizontal direction from the heat dissipation member 330 with the gap G and the second support film 450 being interposed between the first support film 400 and the heat dissipation member 330. The first support film 400 and the heat dissipation member 330 spaced apart from each other may be disposed parallel to each other. A bonding layer 410 may bond the first support film 400 to the lower surface 101 of the display panel 100 in the second area A2 at a position overlapping the driving chip IC in a vertical direction.

The first support film 400 may be made of at least one of, for example, polyethylene terephthalate (PET), polycarbonate (PC), and polymethyl methacrylate (PMMA). The first support film 400 may be most preferably made of polyethylene terephthalate (PET), but the present disclosure is not limited thereto.

The first support film 400 may be made of a film with high tensile modulus or high light transmittance. When the first support film 400 is made of a film with a high tensile modulus, the first support film 400 may support the flexible display panel 100, protect the lower surface 101 of the display panel 100, and prevent the formation of cracks in the display panel 100 during a process of mounting the driving chip IC on the display panel 100. When the driving chip IC is mounted on the second area A2 of the display panel 100, pressure may be applied to the second area A2. Here, since the first support film 400 disposed on the lower surface 101 of the display panel 100 corresponding to the second area A2 has a high tensile modulus, the first support film 400 may prevent cracks from being formed in the wirings of the non-display area NDA due to the pressure applied during the process of mounting the driving chip IC.

The first support film 400 may be made of a film with high light transmittance, and the light transmittance of the first support film 400 may be, but is not limited to, about 80% or more. When the first support film 400 is made of a film with high transmittance, the driving chip IC may be mounted on the display panel 100 by high-pressure bonding in the second area A2 to which the first support film 400 is bonded. An optical microscope or the like can view or inspect the driving chip IC through the first support film 400 to determine whether the driving chip IC has been properly mounted. Here, since the light transmittance of the first support film 400 located in the second area A2 where the driving chip IC is mounted is high, the mounted state of the driving chip IC can be easily inspected. Accordingly, the problem of undetected defects caused by compression of the driving chip IC can be avoided.

The display panel 100 may be folded along the folding axis FX particularly in the case in which the first area A1 is spaced apart from the second area A2. In contrast, if the first support film 400 was in the first area A1, which may be foldable, the first support film 400 could change the position of a neutral plane in the first area A1 when the display panel 100 is bent or folded. However, since the first support film 400 is not disposed in the first area A1 in the present disclosure, the first support film area A1 does not change the position of the neutral plane.

The overall thickness of the display device 1 may increase if the first support film 400 was located in the first area because of the increase in the number of stacked structures in the first area A1 which is the display area DA. However, according to the present disclosure, the first support film 400 is disposed in the second area A2 which is the non-display area NDA and is not disposed in the first area A1 which is the display area DA. Therefore, the number stacked structures can be reduced in the first area A1, which includes the display area DA, thereby reducing the overall thickness of the display device 1.

In addition, since the first support film 400 is not disposed in the first area A1, the number of stacked structures in the first area A1, which includes the display area DA, may be reduced thereby reducing manufacturing costs.

As described above, the first support film 400 is not disposed in the first area A1 but is located on the lower surface 101 of the display panel 100 at a position corresponding to the driving chip IC in the second area A2. Therefore, the first support film 400 can accordingly protect the display panel 100 in the second area A2, and the problems of cracks and driving chip defects can be avoided.

The bonding layer 410 is formed on the lower surface 101 of the display panel 100 and extends in the horizontal direction in the second area A2 and the third area A3. The bonding layer 410 bonds the first support film 400 to the lower surface 101 of the display panel 100 in the second area A2 and bonds the second support film 450 to the lower surface 101 of the display panel 100 in the third area A3. Since the bonding layer 410 is formed in the second area A2 and the third area A3, the first support film 400 and the second support film 450 in different areas A2 and A3 can both be bonded to the lower surface 101 of the display panel 100 using one bonding layer 410. That is, since only one bonding layer 410 is provided in the second area A2 and the third area A3, the number of components for bonding the above films may be reduced, thereby reducing thickness and manufacturing costs. In addition, since the process of bonding each of the above films is simplified, the efficiency of a manufacturing process may be improved.

The bonding layer 410 may have adhesiveness that can attach the first and second support films 400 and 450 and may be formed to have a high storage modulus. The bonding layer 410 may include, for example, one or more of polyester acrylate resin, unsaturated polyester resin, polyurethane acrylate resin, epoxy acrylate resin, epoxy resin, polyether acrylate resin, and polythiol acrylate resin. The bonding layer 410 may include a UV-peelable adhesive, but the present disclosure is not limited thereto. When the bonding layer 410 is made of a UV-peelable adhesive, the adhesive strength of the bonding layer 410 may decrease to 100 gf/in or less (180-degree peeling at 40 mm/sec) in response to UV irradiation. However, the present disclosure is not limited thereto. Here, if the bonding layer 410 is made of a UV-peelable adhesive and its adhesive strength is reduced to 100 gf/in or less (180-degree peeling at 40 mm/sec) after light irradiation, the bonding layer 410 can be easily peeled off during the manufacturing process. Accordingly, process convenience can be improved, and a defect rate can be reduced because no residue or damage is left on a peeled surface.

The storage modulus of the bonding layer 410 may be high, to prevent cracks from being formed by pressure during the process of mounting the driving chip IC. Cracks may be prevented because the bonding layer 410 having a high storage modulus is located in the second area A2 of the display panel 100 where the pressure is applied.

The second support film 450 is disposed in the third area A3 at a position spaced apart from the first support film 400 and contacts the panel bottom cover 300. The gap G is formed in the third area A3 as a space between the first support film 400 and the second support film 450. The second support film 450 is spaced apart from the first support film 400 by the gap G in the horizontal direction. The second support film 450 and the first support film 400 spaced apart from each other may be parallel to each other.

The second support film 450 is bonded to the lower surface 101 of the display panel 100 by the bonding layer 410 in the third area A3 and supports the display panel 100 from below. The second support film 450 may be made of at least one of, for example, polyethylene terephthalate (PET), polycarbonate (PC), and polymethyl methacrylate (PMMA). The first support film 450 may be most preferably made of polyethylene terephthalate (PET), but the present disclosure is not limited thereto.

The second support film 450 is located in an area where bending of the display panel 100 may begin when the display panel 100 is bent. That is, the second support film 450 is located in the third area A3, which is a bending area. The second support film 450 may contact the panel bottom cover 300. Therefore, when the display panel 100 is bent, the second support film 450 can prevent the under-cover panel 300 and the display panel 100 from directly contacting and interfering with each other, thus reducing the risk of crack formation in the wirings of the display panel 100. If the second support film 450 is not provided, bending stress may occur in the area where bending begins, thus increasing the risk of crack formation.

The second support film 450 may additionally support the panel bottom cover 300 while in contact with the panel bottom cover 300. Therefore, when a variable motion, that is, bending of the display panel 100 occurs, the second support film 450 supports the panel bottom cover 300 from the side to stably maintain the position of the panel bottom cover 300.

In addition, the second support film 450 supports the display panel 100 from below and contacts the panel bottom cover 300 from the side. Therefore, when the display panel 100 is bent, the second support film 450 can support the display panel 100 and the panel bottom cover 300 so that symmetrical positions of structures stacked on the display panel 100 are not affected by the bending operation. As a result, the structures can be bent symmetrically.

The substrate cover layer 500 is disposed on a lower surface of the flexible printed circuit board FPCB at a position in contact with the bonding layer 410 and the first support film 400 of the second area A2 and the display panel 100. The substrate cover layer 500 may be formed in various forms such as an organic layer and may include, for example, one or more of acrylic resin and urethane resin. However, the present disclosure is not limited thereto.

An upper protective layer 600a may be located in the third area A3 on the upper surface 102 of the display panel 100, and an edge of the upper protective layer 600a may be in contact with the substrate cover layer 500. Although only the upper protective layer 600a is illustrated, a lower protective layer (not shown) may also be formed on the bonding layer 410 of the third area A3.

The upper protective layer 600a is located between the polarizer 310 in the first area A1 and the driving chip IC in the second area A2 along the horizontal direction and is disposed on the upper surface 102 of the display panel 100. The upper protective layer 600a may act on the non-display area NDA of the display panel 100 as a neutral plane adjustment layer. The neutral plane adjustment layer 600a may overlap the bendable third area A3 of the non-display area NDA of the display panel 100. Although FIG. 7 shows an embodiment in which the neutral plane adjustment layer 600a is only in the third area A3, a portion of the neutral plane adjustment layer 600a may overlap the first area A1 or the second area A2.

The neutral plane adjustment layer 600a may prevent the formation of cracks in the wirings within the driving layer 120 by relieving the stress applied to the driving layer 120 in the bendable third area A3. More specifically, the driving layer 120 of the display panel 100 may include wirings passing through the non-display area NDA of the first area A1 and the third area A3, and elements in the driving layer 120 may be electrically connected to the driving chip IC through the wirings. The neutral plane adjustment layer 600a adjusts the position of the neutral plane to prevent tensile stress from acting on the wirings located in the third area A3. Here, the neutral plane refers to a plane on which neither compressive stress nor tensile stress acts when the third area A3 of the display panel 100 is bent. For example, when the third area A3 is bent, compressive stress acts on the inside of a bending curvature, and tensile stress acts on the outside. Therefore, from the inside toward the outside of the curvature, the direction of stress gradually changes from a compression direction to a tension direction. At a certain critical point, there is a transition point where neither compressive stress nor tensile stress acts, and this point becomes the neutral plane. If the position of the neutral plane is adjusted by the neutral plane adjustment layer 600a, compressive stress acts on the wirings in the driving layer 120, thereby reducing the risk of crack formation.

The neutral plane adjustment layer 600a may be made of an organic material. The organic material may be, for example, a photosensitive organic material. For example, the neutral plane adjustment layer 600a may include one or more of acrylic resin and urethane resin.

Although FIG. 7 shows an embodiment in which the neutral plane adjustment layer 600a is spaced apart from the driving chip IC, the present disclosure is not limited thereto. The neutral plane adjustment layer 600a may extend to the driving chip IC and may cover a portion of the driving chip IC. In this case, the coupling reliability between the driving chip IC and the display panel 100 may be improved.

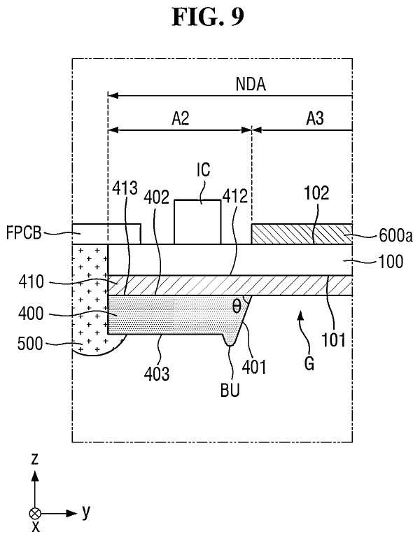

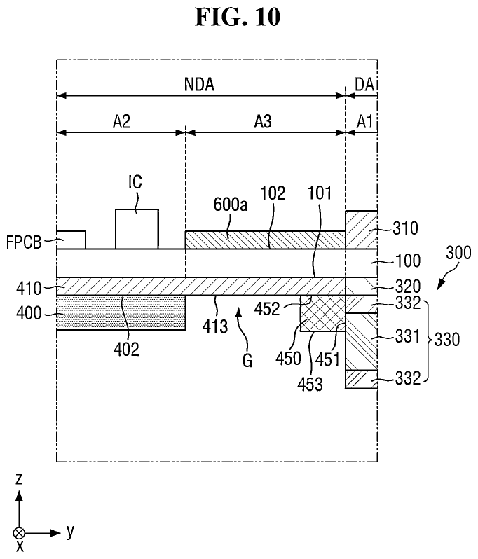

FIG. 8 is an enlarged view focused on the first area A1 of FIG. 7. FIG. 9 is an enlarged view focused on the second area A2 of FIG. 7. FIG. 10 is an enlarged view of the second area A2, the third area A3, and a part of the first area A1 according to a first embodiment of the display device 1 shown in FIG. 7.

The panel bottom cover 300 of FIG. 8 may include a side or inner surface 301 closest to the gap G, an upper surface 302 facing a lower surface of the bonding layer 410, and a lower surface 303 opposite the upper surface 302. The upper surface 302 of the panel bottom cover 300 contacts the lower surface 101 of the display panel 100. An angle formed by the inner surface 301 of the panel bottom cover 300 and the lower surface 101 of the display panel 100 may be a right angle. In this case, the panel bottom cover 300 may have a rectangular cross-sectional shape as illustrated in FIG. 8. However, the shape of the panel bottom cover 300 is not limited to the rectangular cross-sectional shape.

The bonding layer 410 as shown in FIG. 9 may include an upper surface 412 contacting the lower surface 101 of the display panel 100 and the lower surface 413, i.e., a first surface opposite the upper surface 412.

The first support film 400 as shown in FIG. 9 may include an inner or side surface 401 adjacent to the gap G, an upper surface 402 contacting the lower surface 413 of the bonding layer 410, and a lower surface 403, i.e., a first surface opposite the upper surface 402. The upper surface 402 of the first support film 400 contacts the lower surface 413 of the bonding layer 410. An inclination angle θ formed by the inner surface 401 of the first support film 400 exposed to the gap G in the third area A3 and the lower surface 413 of the bonding layer 410 may be an acute angle. For example, the inclination angle θ may be greater than 0 and less than about 70 degrees, but the present disclosure is not limited thereto. Also, the inclination angle θ may be smaller than the angle formed by the inner surface 301 of the panel bottom cover 300 and the lower surface 413 of the bonding layer 410, but the present disclosure is not limited thereto.

The first support film 400 may further include a burr pattern BU protruding downward from the lower surface 403 of the support film 400 and may extend along the inner surface 401 adjacent to the gap G. The burr pattern BU may extend in the same direction as the gap G, for example, along the first direction x. The burr pattern BU of the first support film 400 may be formed when irradiating laser light on the first support film 400 during the manufacturing process. The burr pattern BU may be formed as the thermal energy of the laser light melts a portion of the first support film 400.

The second support film 450 as shown in FIG. 10 may include an inner or side surface 451 contacting the heat dissipation member 330, an upper surface 452 contacting the lower surface 413 of the bonding layer 410, and a lower surface 453 opposite the upper surface 452. FIG. 10 shows a first embodiment in which the second support film 450 may be located in the third area A3 and may contact the heat dissipation member 330. The second support film 450 is spaced apart from the first support film 400 by the gap G, and the upper surface 452 of the second support film 450 is attached to the lower surface 413 of the bonding layer 410 as is the upper surface 402 of the first support film 400. More particularly, the lower surface 413 of the bonding layer 410 in the second area A2 is bonded to the first support film 400, a portion of the lower surface 413 of the bonding layer 410 in the third area A3 is exposed to the gap G, and the other portion of the lower surface 413 of the bonding layer 410 in the third area A3 is bonded to the second support film 450.

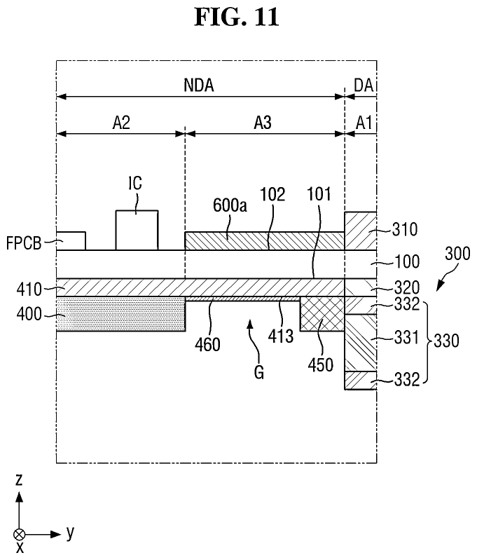

FIG. 11 is an enlarged view of the second area A2, the third area A3, and a part of the first area A1 according to a second embodiment of the display device 1 shown in FIG. 7. A description of components shown in FIG. 11 that are the same as the components described above with reference to FIG. 10 may be omitted below.

A second support film 450 of FIG. 11, as the second embodiment, may be located in the third area A3 and may be connected to a first support film 400 by a support film connection portion 460. The support film connection portion 460 is located in the third area A3 together with the second support film 450 and contacts a lower surface 413 of a bonding layer 410 in a gap G. The support film connection portion 460 may be formed integrally with the first and second support films 400 and 450. For example, when the gap G is formed in the third area A3 by irradiating laser light onto a support film layer 400a in a raw state, which will be described later, the whole of the support film layer 400a may be removed from the gap G so that the lower surface 413 of the bonding layer 410 is exposed to the gap G as illustrated by the first embodiment shown in FIG. 10 Alternatively, only a portion of the support film layer 400a may be removed so that the remaining portion of the support film layer 400a forms the support film connection portion 460 as illustrated by the second embodiment shown in FIG. 11. Alternatively, a separate support film connection portion 460 may be prepared and then attached to the lower surface 413 of the bonding layer 410.

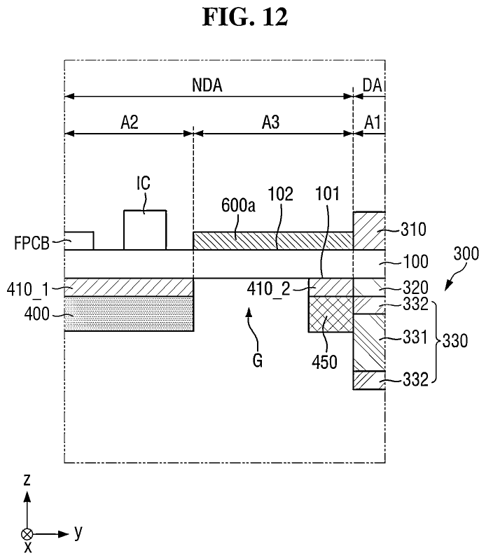

FIG. 12 is an enlarged view of the second area A2, the third area A3, and a part of the first area A1 according to a third embodiment of the display device 1 shown in FIG. 7. A description of components shown in FIG. 12 that are the same as the components described above with reference to FIG. 10 may be omitted below.

A second support film 450 shown in FIG. 12, as the third embodiment, may be located in the third area A3 and may be bonded by a separate second bonding layer 410_2 formed in the third area A3. In the first embodiment as shown in FIG. 10, the second support film 450 is bonded to the display panel 100 by one bonding layer 410 that spans the second area A2 and the third area A3. However, in the third embodiment as shown in FIG. 12, the second support film 450 may be bonded to the display panel 100 by the separate second bonding layer 410_2 provided in the third area A3, and a first support film 400 may be bonded to the display panel 100 by a separate first bonding layer 410_1 provided in the second area A2. In short, the lower surface 101 of the display panel 100 is covered by the bonding layer 410 in the embodiment shown in FIG. 10, but the lower surface 101 of the display panel 100 is exposed to the gap G the embodiment shown in FIG. 12.

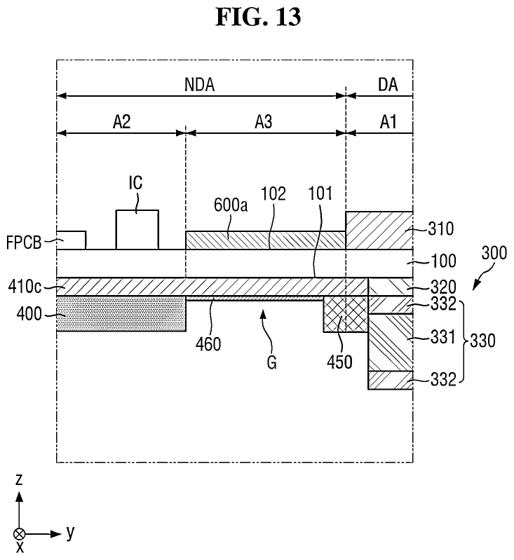

FIG. 13 is an enlarged view of the second area A2, the third area A3, and a part of the first area A1 according to a fourth embodiment of the display device 1 shown in FIG. 7. A description of components shown in FIG. 13 that are the same as the components described above with reference to FIG. 10 or 11 may be omitted below.

A second support film 450 of FIG. 13, as the fourth embodiment, may cross a boundary between the third area A3 and the first area A1. The second support film 450 is located in the third area A3 in the second embodiment as shown in FIG. 11. However, in the fourth embodiment as shown in FIG. 13, a portion of the second support film 450 may be located in the third area A3, and the other portion of the second support film 450 may be located in the first area A1.

The bonding layer 410 is in the second and third areas A2 and A3 in the second embodiment shown in FIG. 11. However, in the fourth embodiment shown in FIG. 13, a bonding layer 410c may be in the second and third areas A2 and A3 and a part of the first area A1.

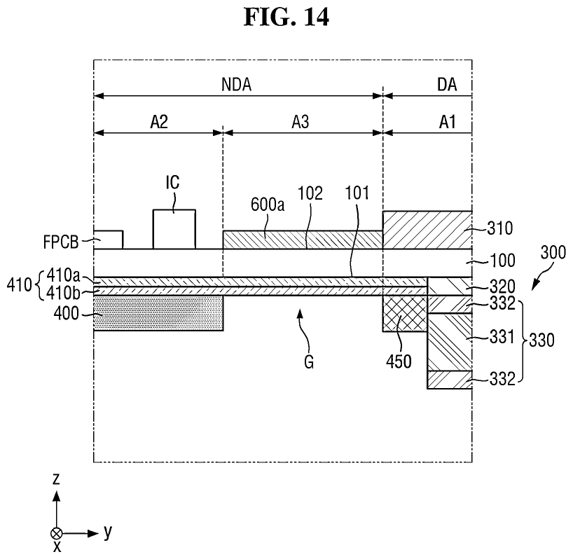

FIG. 14 is an enlarged view of the second area A2, the third area A3, and a part of the first area A1 according to a fifth embodiment of the display device shown in FIG. 7. A description of components shown in FIG. 14 that are the same as the components described above with reference to FIG. 10 may be omitted below.

A second support film 450 of FIG. 14, as the fifth embodiment, is located in the first area A1. The second support film 450 is in the third area A3 in the first embodiment as shown in FIG. 10. However, in the fifth embodiment as shown in FIG. 14, the second support film 450 may be formed in the first area A1.

The bonding layer 410 is in the second and third areas A2 and A3 in the first embodiment as shown FIG. 10 of the first embodiment. However, in the fifth embodiment as shown in FIG. 14, a bonding layer 410 may be in the second and third areas A2 and A3 and a part of the first area A1. Additionally, the bonding layer 410 in the first embodiment as shown in FIG. 10 is a single layer, but in the fifth embodiment as shown in FIG. 14, the bonding layer 410 may be a double layer that includes a first adhesive layer 410a in contact with a display panel 100 and a second adhesive layer 410b in contact with the first adhesive layer 410a.

The first adhesive layer 410a may be a fixed adhesive layer 410a with an adhesive strength that remains unchanged when exposed to light irradiation or may be an optical coupling adhesive layer 410a with an adhesive strength that increases when exposed to light irradiation. When the first adhesive layer 410a is an optical coupling adhesive layer 410a, the adhesive strength of the first adhesive layer 410a may be 100 gf/inch or less before light irradiation and may be 250 gf/inch or more after light irradiation.

The second support film 450 may be bonded to the second adhesive layer 410b in the first area A1, and the first support film 400 may be bonded to the second adhesive layer 410b in the second area A2. The second adhesive layer 410b may be a light-peelable adhesive layer 410b that has an adhesive strength that light irradiation reduces. When the second adhesive layer 410b is a light-peelable adhesive layer 410b, the adhesive strength of the second adhesive layer 410b may be 250 gf/inch or more before light irradiation and may decrease to 50 gf/inch or less after light irradiation. In this case, the second adhesive layer 410b can be easily peeled off during a manufacturing process. Accordingly, manufacture of the fifth embodiment may have improved process convenience and a reduced defect rate because no residue or damage is left on a peeled surface.

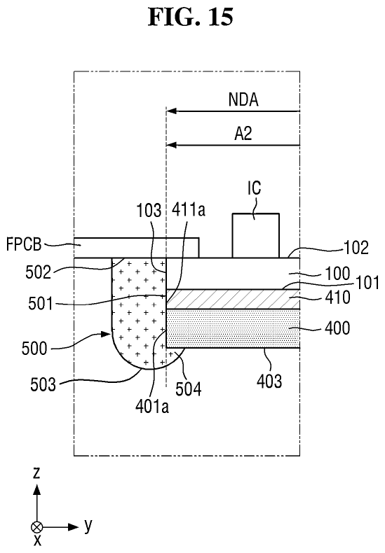

FIG. 15 is an enlarged view of the second area A2 and a flexible printed circuit board bonding area of the display device 1 shown in FIG. 7.

The substrate cover layer 500 of FIG. 15 may include a cover layer side surface 501 in contact with respective side surfaces 401a, 411a and 103 of the first support film 400, the bonding layer 410, and the display panel 100. A cover layer upper surface 502 of the substrate cover layer 500 is in contact with the lower surface, i.e., a first surface of the flexible printed circuit board FPCB, and a cover layer lower surface 503 is a first surface opposite the cover layer upper surface 502.

The cover layer upper surface 502 supports the flexible printed circuit board FPCB from below the flexible printed circuit board FPCB, and the cover layer side surface 501 supports the respective side surfaces 401a, 411a and 103 of the support film 400, the bonding layer 410, and the display panel 100 from the side.

The cover layer lower surface 503 extends toward the side surface 401a of the support film 400, and a cover portion 504 of the substrate cover layer 500 may further extend onto the lower surface 403 of the support film 400. The cover portion 504 may be formed to cover, that is, seal a portion of the lower surface 403 of the support film 400. Therefore, the substrate cover layer 500 may prevent the penetration of moisture into the flexible printed circuit board FPCB and the driving chip IC connected to the flexible printed circuit board FPCB, thereby preventing corrosion due to the moisture.

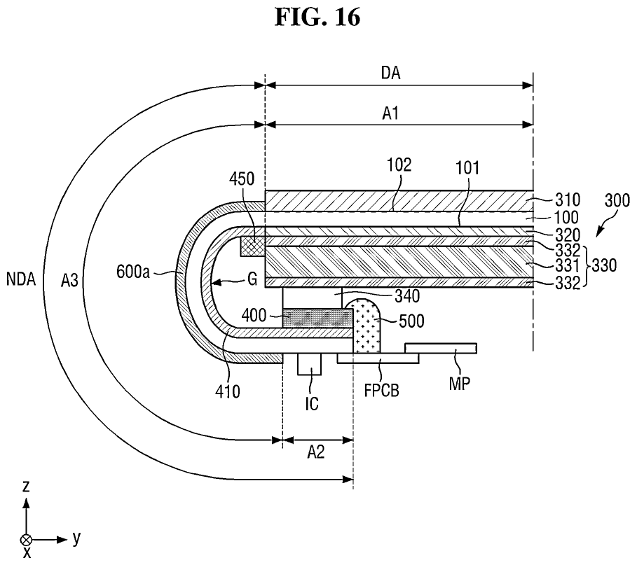

FIG. 16 is a cross-sectional view of a portion of the display device 1 of FIG. 7 when the display panel 100 is in a bent state. More specifically, FIG. 16 shows a cross-sectional view of the non-display area NDA of the display panel 100 when in a bent state. The display area DA of the display panel 100 may remain unbent when the display panel 100 is in the bent state.

Referring to FIG. 16, an end of the display panel 100 of the display device 1 may be bent toward the bottom of the display panel 100 causing bending about the bending axis BX (see FIG. 1) extending along the first direction x in the third area A3. Since the gap G overlapping the third area A3 is between the second support film 450, which contacts the panel bottom cover 300, and the first support film 400, the display panel 100 can be bent more easily. Here, the first support film 400 is coupled to the bending adhesive member 340 of the panel bottom cover 300, so that the bending adhesive member 340 fixes the bending position of the display panel 100.

The alignment of the bent state of the display panel 100 may depend on the position at which the first support film 400 is attached to the bending adhesive member 340. For example, edges of the display panel 100 and the first support film 400, may be aligned with the bending adhesive member 340 in a row in the vertical direction. Alternatively, as illustrated in FIG. 16, the display panel 100 and the first support film 400 may be fixed to form a step with the bending adhesive member 340 by moving the first support film 400 to the right and fixing the first support film 400 in that position.

Since a part of the non-display area NDA of the display panel 100 is bent, the area of the non-display area NDA of the display device 1 which is visible from above can be reduced, and a bezel width of the display device 1 may have a reduced bezel width. In addition, the neutral plane adjustment layer 600a overlapping the third area A3 of the display panel 100 may prevent the formation of cracks in the wirings of the display panel 100 in the third area A3 and may improve the reliability of the display device 1.

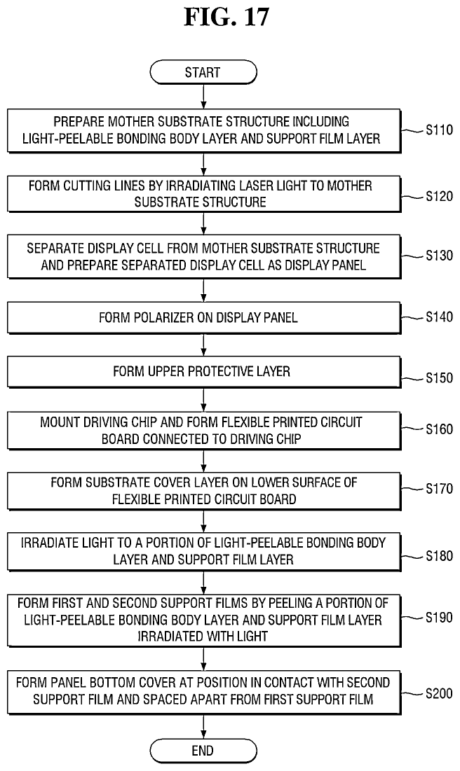

A method of manufacturing the display device 1 according to the present disclosure will now be described with reference to FIGS. 17 through 25.

The method of manufacturing the display device 1 according to the present disclosure may include the following operations.

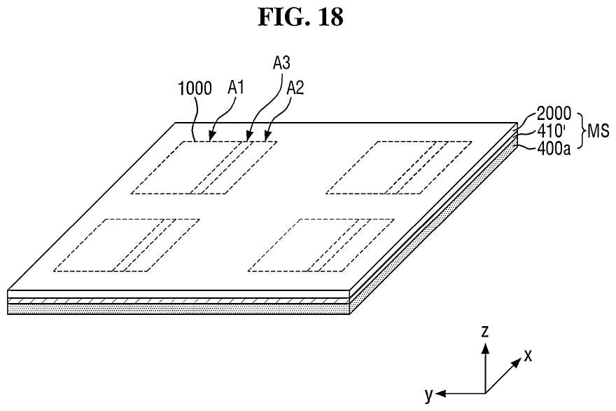

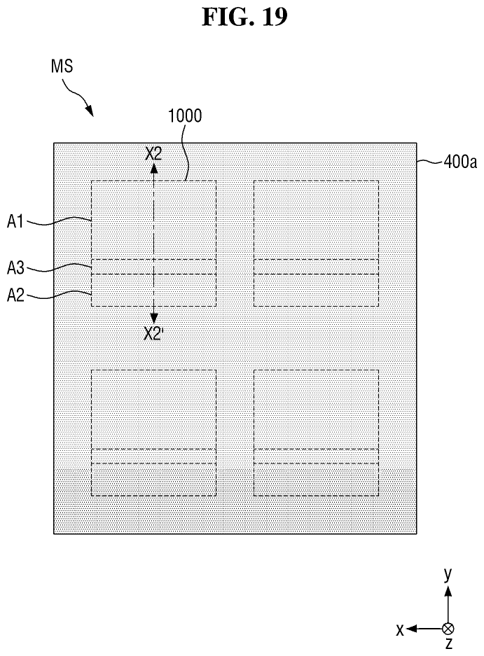

First, a mother substrate structure MS may be prepared (operation S110 in FIG. 17). Referring to FIGS. 18 and 19, a mother substrate 2000 may be prepared, a light-peelable bonding body layer 410′ may be formed on a lower surface of the mother substrate 2000, and a support film layer 400a in a raw state may be bonded to the light-peelable bonding body layer 410′ to produce the mother substrate structure MS. The mother substrate structure MS may include a plurality of display cells 1000 and a dummy area other than the display cells 1000. Each display cell 1000 may be separated from the mother substrate 2000 to form a display panel 100. Each display cell 1000 may include a first area A1, a second area A2, and a third area A3. The cross-sectional stacked structure of each display cell 1000 may be the same as that of the display panel 100 illustrated in FIG. 5 or 6. The dummy area may be a portion of the mother substrate structure MS other than the display cells 1000 and may be removed.

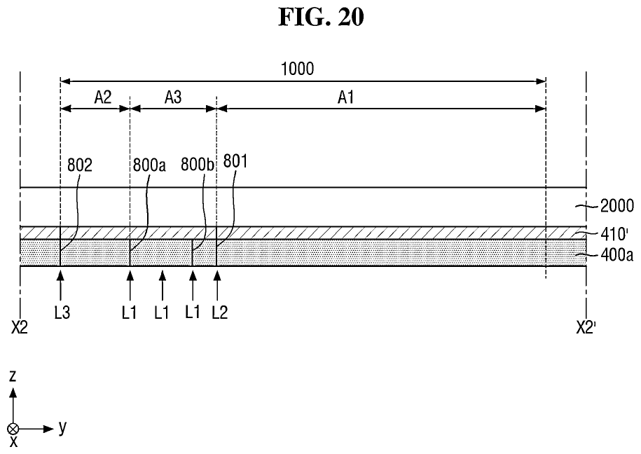

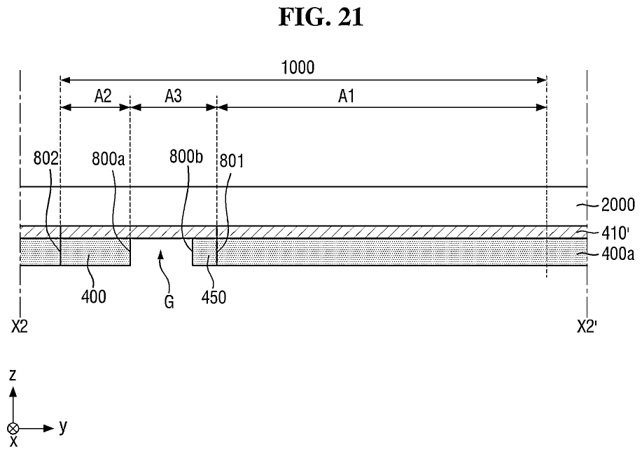

Second, cutting lines, e.g., cutting lines 800a, 800b, 801 and 802 shown in FIG. 20, may be formed (operation S120 in FIG. 17). Referring to FIGS. 20 through 22, laser light L1 through L3 may be irradiated from below the support film layer 400a of the mother substrate structure MS to cut the support film layer 400a alone or to cut the light-peelable bonding body layer 410′ and the support film layer 400a together. Here, as the laser light L1 through L3 is irradiated in lines extending along the first direction x, which is the short-side direction of the display panel 100, first through third cutting sections are formed. The first cutting section is a cutting section formed in the support film layer 400a by irradiating the laser light L1 on an area extending into the third area from a boundary between the second area A2 and the third area A3. The first cutting section includes a first line 800a which is a boundary line between the second area A2 and the third area A3, a second line 800b formed in a part of the third area A3, and a gap G of FIG. 21 located between the first line 800a and the second line 800b. An operation S190, which will be described below, forms the gap G is defined as a space that separates a first support film 400 and a second support film 450.

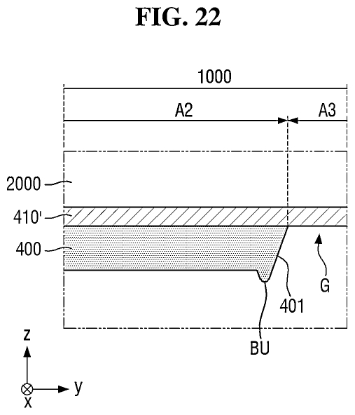

A burr pattern BU of FIG. 22, which is formed as the laser light L1 is irradiated onto the support film layer 400a, is disposed adjacent to the gap G. The burr pattern BU may be formed on the first line 800a, which is a cutting line of the support film layer 400a, adjacent to the gap G. The burr pattern BU may be formed as the thermal energy of the laser light L1 melts a portion of the support film layer 400a. Here, the laser light L1 may be, but is not limited to, light from a CO₂ laser, which provides a high energy efficiency. The burr pattern BU may be continuously formed in the boundary area between the third area A3 and the second area A2 along the first direction x, which is the short-side direction of the display panel 100.

The second cutting section is a cutting section is in a boundary area between the third area A3 and the first area A1 where a second cutting line 801 is formed in the support film layer 400a and the light-peelable bonding body layer 410′ by irradiating the mother substrate MS with the laser light L2.

The third cutting section is a cutting section is in a boundary area between the dummy area and the second area A2 where a third cutting line 802 is formed in the support film layer 400a and the light-peelable bonding body layer 410′ by irradiating the mother substrate MS with the laser light L3.

Here, although the laser light is illustrated in the order of L1, L2, and L3 to indicate the first through third cutting sections, the order of irradiating laser light to form each cutting section is not limited to the above order.

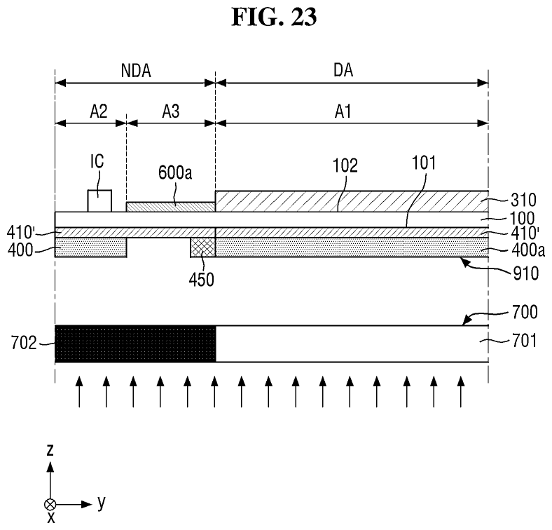

Third, the display panel 100 may be prepared (operation S130 in FIG. 17). Each display cell 1000 may be separated from the mother substrate MS by removing the dummy area from the mother substrate structure MS based on the third cutting line 802. Referring to FIG. 23, each separated display cell 1000 may be prepared as the display panel 100 with the light-peelable bonding body layer 410′ on the lower surface 101 of the display panel 100. On the light-peelable bonding body layer 410′, the support film layer 400a is in the first area A1, the first support film 400 is in the second area A2, and the second support film 450, and the gap G in the third area A3.

In this example, each display cell 1000 is separated from the mother substrate structure MS using the third cutting line 802 after the first cutting section formed by the first and second lines 800a and 800b and the second cutting section including the second cutting line 801 are formed. However, the present disclosure is not limited thereto. After each display cell 1000 is separated using the third cutting line 802, a laser irradiation process for forming the first and second cutting sections may be performed on the display panel 100 prepared as the separated display cell 1000.

Fourth, a polarizer 310 may be formed (operation S140 in FIG. 17). The polarizer 310 may be formed on an upper surface 102 of the display panel 100 in the first area A1.

Fifth, an upper protective layer 600a may be formed (operation S150 in FIG. 17). The upper protective layer 600a may be formed on the upper surface 102 of the display panel 100 in the third area A3. Although only the upper protective layer 600a is formed in the illustrated embodiment, an operation of forming a lower protective layer on the light-peelable bonding body layer 410′ may also be performed.

Sixth, a driving chip IC and a flexible printed circuit board FPCB may be formed and mounted (operation S160 in FIG. 17). The driving chip IC may be mounted on the upper surface 102 of the display panel 100 in the second area A2, and an end of the flexible printed circuit board FPCB may be coupled to the display panel 100 in the second area A2.

Seventh, a substrate cover layer 500 may be formed (operation S170 in FIG. 17). The substrate cover layer 500 may be formed on a lower surface of the flexible printed circuit board FPCB and may be disposed adjacent to an edge of the display panel 100. Here, the flexible printed circuit board FPCB and the substrate cover layer 500 may be the same as those illustrated in FIG. 7 and thus are not illustrated in FIGS. 23 through 25.

Eighth, light may be irradiated (operation S180 in FIG. 17). Referring to FIG. 23, a mask 700 that can selectively pass light may be placed under the support film layer 400a, and then light may be irradiated. The light-peelable bonding body layer 410′ and the support film layer 400a located in the first area A1 may be in a light irradiation area, and light may be irradiated into the light irradiation area through a light transmitting portion 701 of the mask 700. The light-peelable bonding body layer 410′ and the support film layer 400a located in the second area A2 and the third area A3 may be in a non-light irradiation area a light blocking portion 702 of the mask 700 may prevent light from irradiating this non-light irradiation area. Here, the light Irradiation may be irradiation of UV laser light. When UV light is irradiated, the adhesive strength of the light-peelable bonding body layer 410′ may be weakened in the first area A1 irradiated with the light. On the other hand, the adhesive strength of the light-peelable bonding body layer 410′ may be maintained in the second area A2 and the third area A3, which are not irradiated with the light. For example, the adhesive strength of the light-peelable bonding body layer 410′ may be 250 gf/inch or more before UV irradiation but may decrease to 100 gf/inch or less (180-degree peeling at 40 mm/sec) after the UV irradiation. Therefore, the support film layer 400a in the light irradiation area can be easily removed. Accordingly, since the light-peelable bonding body layer 410′ and the support film layer 400a do not remain in a peeling area 910 which is a light irradiation area, they do not cause defects or leave damage to a peeled surface, thereby reducing a defect rate. In addition, issues such as tearing during the peeling process can be suppressed. The adhesive strength may also be reduced to 20 gf/inch or less, but the present disclosure is not limited thereto.

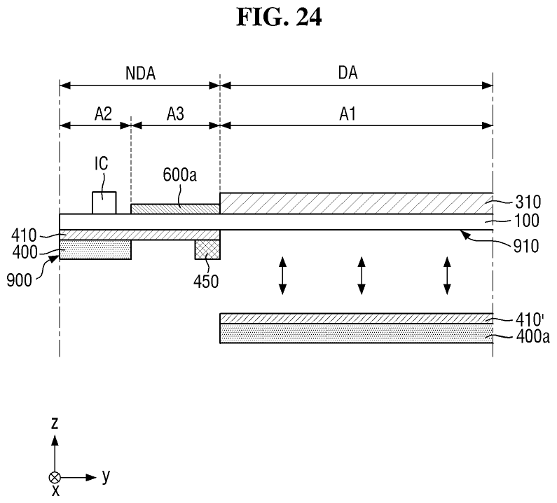

Ninth, first and second support films 400 and 450 may be formed (operation S190 in FIG. 17). Referring to FIG. 24, the support film layer 400a located in the first area A1, which is a light irradiation area, may be removed by peeling it off along the second cutting line 801 of FIG. 20. The adhesive strength of the light-peelable bonding body layer 410′ located in the first area A1, which is a light irradiation area, is reduced by light irradiation. Therefore, the support film layer 400a in the first area A1 can be easily peeled and removed. The area from which the support film layer 400a has been removed is the peeling area 910.

The light-peelable bonding body layer 410′ located in the second and third areas A2 and A3, which are non-light irradiation areas, maintains its adhesive strength because it is not irradiated with light. Therefore, the light-peelable bonding body layer 410′ and the first and second support films 400 and 450 located in the second and third areas A2 and A3 can be kept bonded to each other. Here, the area where the light-peelable bonding body layer 410′ and the first and second support films 400 and 450 are kept bonded to each other may be a bonding area 900. Accordingly, the first and second support films 400 and 450 may be finally formed in the second and third areas A2 and A3 formed as the bonding area 900 without being peeled off.

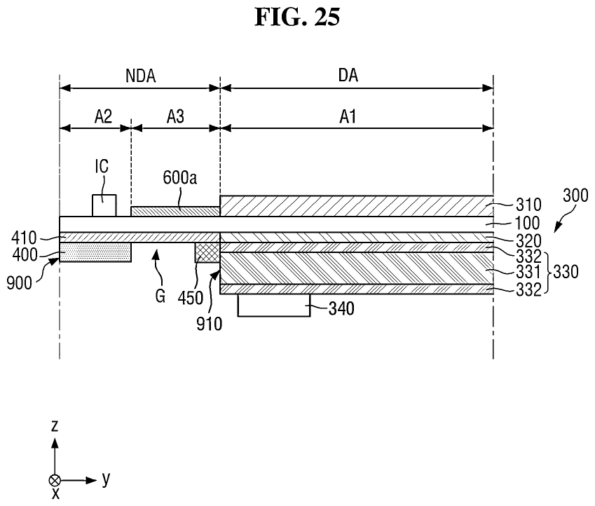

Tenth, a panel bottom cover 300 may be formed (operation S200 in FIG. 17). Referring to FIG. 25, in the panel bottom cover 300, an adhesive member 320 is bonded to the display panel 100 in the first area A1 which is the peeling area 910. Here, the panel bottom cover 300 contacts the second support film 450 of the bonding area 900 and is spaced apart from the first support film 400 of the bonding area 900.

Finally, the first support film 400 of the second area A2 and the second support film 450 of the third area A3 share a bonding layer 410 formed over the second and third areas A2 and A3. The first support film 400 of the second area A2 and the second support film 450 of the third area A3 may be kept bonded to a lower surface 101 of the display panel 100 by the bonding layer 410 with the gap G of the third area A3 between them. Through these processes, the display device 1 according to the present disclosure can be manufactured.

As described above, the manufacturing method of the present disclosure may reduce the risk of crack formation in the wirings of the display panel 100 when the display panel 100 is bent and which can reduce thickness and can reduce manufacturing costs of the display device 1.

In concluding the detailed description, those skilled in the art will appreciate that many variations and modifications can be made to the described embodiments without substantially departing from the principles of the present disclosure. Therefore, this disclosure uses the example embodiments in a generic and descriptive sense only and not for purposes of limitation. Each component specifically described herein or shown in the drawings may be modified or altered for different uses or applications, and such modifications or alterations should be construed as being included in the scope defined in the appended claims.

What is claimed is:

1. A display device comprising:
a display panel comprising a first area comprising a display area, a second area spaced apart from the first area, and a bendable third area located between the first area and the second area;
a bonding layer disposed in the second area and the third area of the display panel and located on a first surface of the display panel;
a panel bottom cover disposed in the first area of the display panel and located on the first surface of the display panel;
a first support film disposed in the second area of the display panel and bonded to the bonding layer;
a second support film disposed in the third area of the display panel and bonded to the bonding layer; and
a gap provided in the third area to separate the first support film and the second support film from each other.

2. The display device of claim 1, wherein the bonding layer comprises a light-peelable adhesive of a type having an adhesive strength of 100 gf/inch or less after light irradiation.

3. The display device of claim 1, wherein the first support film further comprises a burr pattern protruding downward from a first surface of the first support film along an inner surface adjacent to the gap.

4. The display device of claim 3, wherein an angle formed by the inner surface on which the burr pattern is formed and a first surface of the bonding layer which contacts the first support film is 70 degrees or less.

5. The display device of claim 1, further comprising a driving chip disposed in the second area of the display panel and located on a second surface of the display panel opposite the first surface of the display panel.

6. The display device of claim 5, further comprising:
a flexible printed circuit board electrically connected to the driving chip of the second area; and
a substrate cover layer formed on a first surface of the flexible printed circuit board,
wherein an end of the flexible printed circuit board is bonded to the second area of the display panel adjacent to an edge of the display panel, and the substrate cover layer is located on the first surface of the flexible printed circuit board at the edge of the display panel and contacts the display panel, the bonding layer and the first support film in the second area.

7. The display device of claim 6, wherein the substrate cover layer further comprises a cover portion extending from a first surface located on a lower side of the substrate cover layer toward the first support film which contacts the substrate cover layer, the cover portion covering a portion of a lower area of the first support film.

8. The display device of claim 1, further comprising a protective layer formed on the second surface of the display panel opposite the first surface of the display panel in the third area.

9. The display device of claim 1, further comprising a support film connection portion formed on the first surface of the bonding layer exposed to the gap and connecting the first support film and the second support film.

10. The display device of claim 1, wherein the first surface of the display panel is exposed to the gap in the third area, and the bonding layer comprises a first bonding layer disposed in the second area and a second bonding layer spaced apart from the first bonding layer with the gap interposed therebetween in the third area.

11. The display device of claim 1, wherein the bonding layer and the second support film extend to a part of the first area to additionally lie in the first area, a side surface of the bonding layer and a side surface of the second support film face a side surface of the panel bottom cover, and the display device further comprises a support film connection portion formed on the first surface of the bonding layer in the gap and connecting the first support film and the second support film.

12. A display device comprising:
a display panel comprising a first area comprising a display area, a second area spaced apart from the first area, and a bendable third area located between the first area and the second area;
a bonding layer disposed in the second area and the third area of the display panel and located on a first surface of the display panel;
a first support film disposed in the second area of the display panel and bonded to the bonding layer;
a second support film disposed in the third area of the display panel at a position spaced apart from the first support film and bonded to the bonding layer;
a flexible printed circuit board having an end bonded to a distal area of the display panel in the second area; and
a substrate cover layer formed on a first surface of the flexible printed circuit board.

13. The display device of claim 12, wherein the substrate cover layer comprises a cover portion extending from a first surface located on a lower side of the substrate cover layer toward the first support film which contacts the substrate cover layer, the cover portion covering a portion of a lower area of the first support film.

14. The display device of claim 12, wherein the bonding layer comprises a light-peelable adhesive of a type having an adhesive strength of 100 gf/inch or less after light irradiation.

15. The display device of claim 12, further comprising a panel bottom cover disposed in the first area of the display panel, contacting the bonding layer and the second support film, and located on the first surface of the display panel.

16. The display device of claim 15, wherein
the panel bottom cover comprises an adhesive member bonded to the first surface of the display panel in the first area, a heat dissipation member bonded to the adhesive member and dissipating heat of the display panel and a bending adhesive member bonded to the heat dissipation member and fixing a bending position of the display panel when the display panel is bent,
the third area comprises a gap which is a space formed between the first support film and the second support film, and
the first support film further comprises a burr pattern protruding downward from a first surface of the first support film along an inner surface adjacent to the gap.

17. The display device of claim 16, further comprising a driving chip disposed in the second area of the display panel and located on a second surface of the display panel opposite the first surface of the display panel.

18. The display device of claim 12, further comprising a protective layer formed on the second surface of the display panel opposite the first surface of the display panel in the third area.

19. A display device comprising:
a display panel comprising a first area comprising a display area, a second area spaced apart from the first area, and a bendable third area located between the first area and the second area;
a panel bottom cover disposed in the first area of the display panel and located on a first surface of the display panel;
a bonding layer disposed in the second area, the third area and a part of the first area of the display panel, contacting the panel bottom cover of the first area, and located on the first surface of the display panel;
a first support film disposed in the second area of the display panel and bonded to the bonding layer;
a second support film disposed in the first area of the display panel, contacting the panel bottom cover of the first area, and bonded to the bonding layer; and
a gap provided in the third area of the display panel as a space between the first support film and the second support film,
wherein the bonding layer has a first surface exposed to the gap in the third area and comprises a first adhesive layer located on the first surface of the display panel and a second adhesive layer contacting the first adhesive layer.

20. A method of manufacturing a display device having a display panel which comprises a first area comprising a display area, a second area spaced apart from the first area, and a bendable third area comprising a gap between the first area and the second area, the method comprising:
preparing a mother substrate structure which comprises a light-peelable bonding body layer and a support film layer;
forming cutting lines in the mother substrate structure and forming a first support film in the second area and a second support film in the third area and forming the gap between the first and second support films;
separating a display cell from the mother substrate structure to prepare the display panel;
selectively irradiating light to the first area of the display panel;
peeling and removing the support film layer of the first area irradiated with the light; and
forming a panel bottom cover in the first area from which the support film layer has been peeled off, such that the panel bottom cover contacts the second support film of the third area.
